(19) United States
(12) Patent Application Publication
(10) Pub. No.: US 2008/0191341 A1
(43) Pub. Date: Aug. 14, 2008

(54) ELECTRONIC APPARATUS AND SEMICONDUCTOR PACKAGE

(75) Inventor: Shigeki Nishiyama, Hino-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/022,714

(22) Filed: Jan. 30, 2008

(30) Foreign Application Priority Data
Feb. 14, 2007 (JP) 2007033872

(51) Int. Cl. H01L 23/40

(52) U.S. Cl. 257/719; 257/E23.084

(57) ABSTRACT

According to one embodiment, an electronic apparatus is provided with a semiconductor package, a heat receiving plate, and a gap adjusting member. The semiconductor package includes a substrate and a silicon die mounted on the substrate. The heat receiving plate is opposed to the silicon die and thermally connected to the silicon die. The gap adjusting member is disposed between the heat receiving plate and a region of the substrate apart from the silicon die and serves to reduce a gap which exists between the substrate and the heat receiving plate.

### CROSS-REFERENCE TO RELATED APPLICATIONS

This application is based upon and claims the benefit of priority from Japanese Patent Application No. 2007-033872, filed Feb. 14, 2007, the entire contents of which are incorporated herein by reference.

### BACKGROUND

1. Field

One embodiment of the present invention relates to a semiconductor package, to which a heat receiving plate is to be thermally connected, and an electronic apparatus provided with the semiconductor package.

2. Description of the Related Art

An electronic apparatus, such as a portable computer, is mounted with semiconductor packages including a CPU, graphics chip, etc. Since these semiconductor packages generate heat when they operate, many of them are fitted with a heat receiving plate that promotes heat radiation.

Described in Jpn. Pat. Appln. KOKAI Publication No. 2002-280499 is a cooling module in which a heat sink is thermally connected to a heat generating component. The heat sink of the cooling module is floatably disposed in a cooling module housing. The heat sink is urged toward and pressed against the heat generating component by an elastic member, such as a coil spring. Thus, the heat sink is securely thermally connected to the heat generating component.

Each semiconductor package includes a substrate and a silicon die mounted thereon. The die is raised like a step above a surface of the substrate.

If the heat receiving plate is pressed against the silicon die by the elastic member, it sometimes may tilt heavily against the semiconductor package when the electronic apparatus is being carried about or subjected to an external shock, for example.

If the heat receiving plate tilts heavily, an undue force acts on corner portions of the silicon die. If the angle of contact of the heat receiving plate with the die exceeds a predetermined value, a part of the die may possibly be damaged. With the recent increase of the quantity of heat generated by modern semiconductor packages, heat receiving plates are becoming larger and larger. Use of large-sized heat receiving plates, in particular, may possibly cause the aforesaid damage to the silicon die.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary perspective view of the interior of the portable computer of the first embodiment;

FIG. 3 is an exemplary exploded perspective view showing a semiconductor package and its surroundings of the portable computer of the first embodiment;

FIG. 4 is an exemplary sectional view of the portable computer of the first embodiment;

FIG. 5 is an exemplary enlarged sectional view showing a region of the portable computer enclosed by line FS in FIG. 4;

FIG. 6 is an exemplary exploded perspective view showing a semiconductor package and its surroundings of a portable computer according to a second embodiment of the invention;

FIG. 7 is an exemplary exploded perspective view showing a semiconductor package and its surroundings of a portable computer according to a third embodiment of the invention;

FIG. 8 is an exemplary exploded perspective view showing a semiconductor package and its surroundings of a portable computer according to a fourth embodiment of the invention;

FIG. 9 is an exemplary sectional view of the portable computer of the fourth embodiment;

FIG. 10 is an exemplary sectional view of a portable computer according to a fifth embodiment of the invention;

FIG. 11 is an exemplary exploded perspective view showing a semiconductor package and its surroundings of a portable computer according to a sixth embodiment of the invention;

FIG. 12 is an exemplary exploded perspective view showing a semiconductor package and its surroundings of a portable computer according to a seventh embodiment of the invention;

FIG. 13 is an exemplary sectional view of the portable computer of the seventh embodiment;

FIG. 14 is an exemplary sectional view of a portable computer according to an eighth embodiment of the invention; and

FIG. 15 is an exemplary sectional view of a portable computer according to a modification of any of the embodiments of the invention.

### DETAILED DESCRIPTION

Various embodiments according to the invention will be described hereinafter with reference to the accompanying drawings. In general, according to one embodiment of the invention, an electronic apparatus is provided with a semiconductor package, a heat receiving plate, and a gap adjusting member. The semiconductor package includes a substrate and a silicon die mounted on the substrate. The heat receiving plate is opposed to the silicon die and thermally connected to the die. The gap adjusting member is disposed between the heat receiving plate and a region of the substrate apart from the silicon die and serves to reduce a gap which exists between the substrate and the heat receiving plate.

According to one embodiment of the invention, a semiconductor package to which a heat receiving plate is to be thermally connected, is provided with a substrate, a silicon die mounted on the substrate, and a raised portion provided in a region of the substrate apart from the silicon die and projecting toward the heat receiving plate when the heat receiving plate is attached to the semiconductor package.

Embodiments of the present invention that are applied to portable computers will now be described with reference to the accompanying drawings.

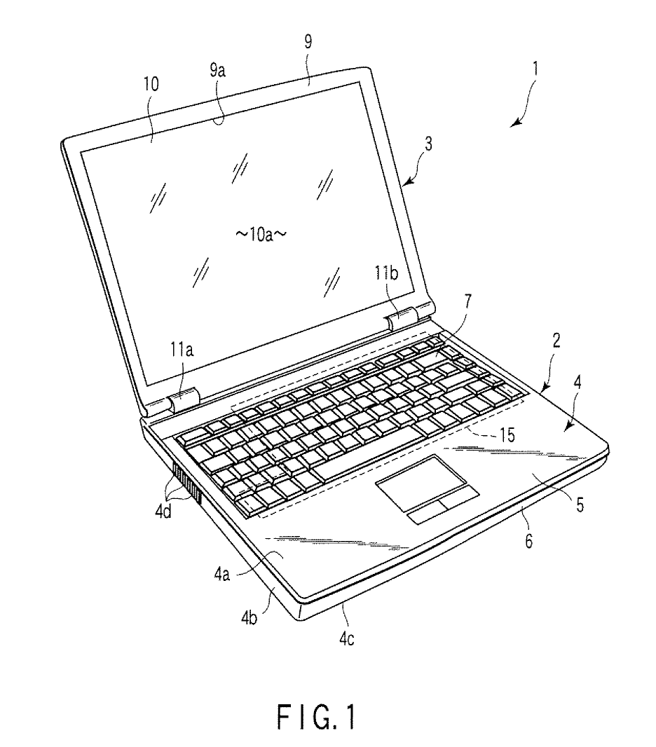

FIGS. 1 to 5 show a portable computer 1 as an electronic apparatus according to a first embodiment of the invention. As shown in FIG. 1, the portable computer 1 is provided with a main body 2 and a display unit 3.

The main body 2 is provided with a box-shaped case 4. The case 4 includes an upper wall 4a, a peripheral wall 4b, and a lower wall 4c. The case 4 is divided into a case cover 5 including the upper wall 4a and a case base 6 including the lower wall 4c. The case cover 5 is combined to the case base 6 from above and removably supported by the base 6. The upper wall 4a supports a keyboard 7. For example, a plurality of exhaust holes 4d open in the peripheral wall 4b.

The display unit 3 is provided with a display housing 9 and a liquid crystal display module 10 therein. The display module 10 includes a display screen 10a. The screen 10a is exposed to the outside of the display housing 9 through an opening 9a in the front face of the housing 9.

The display unit 3 is supported on a rear end portion of the case 4 by a pair of hinge portions 11a and lib. Thus, the display unit 3 is swingable between a closed position in which it lies flat so as to cover the upper wall 4a from above and an open position in which it stands upright so that the upper wall 4a is exposed.

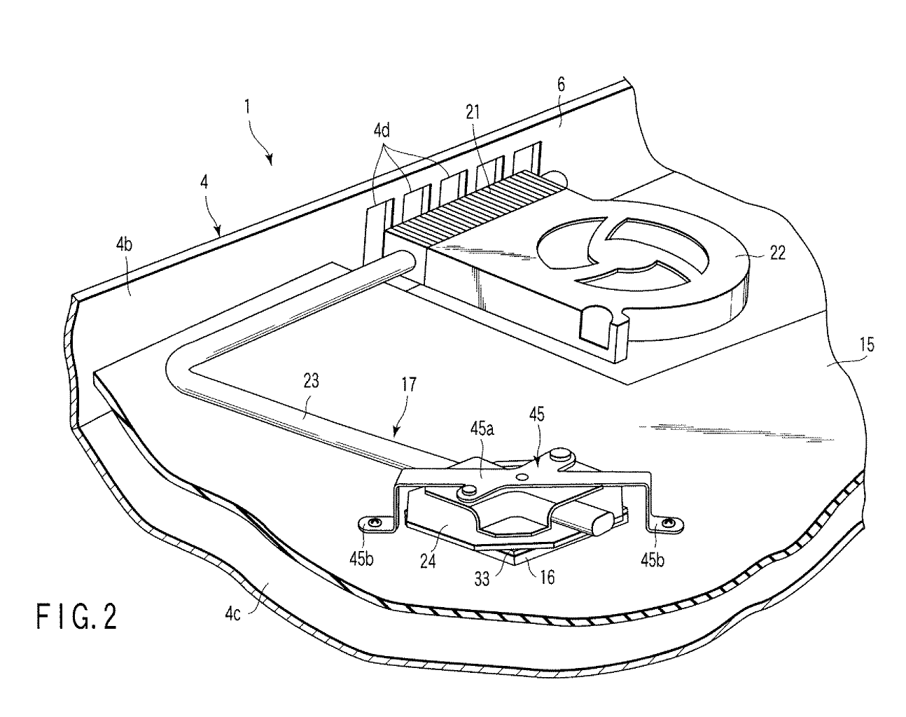

As shown in FIG. 2, the case 4 contains a printed circuit board 15, a semiconductor package 16, and a cooling unit 17. The semiconductor package 16 is mounted on the printed circuit board 15. An example of the semiconductor package 16 is a CPU or graphics chip. However, the semiconductor package stated in the present invention is not limited to this example, but may be any of various components that require heat radiation.

The cooling unit 17 includes radiator fins 21, a cooling fan 22, a heat transfer member 23, and a heat receiving plate 24. The radiator fins 21 face the exhaust holes 4d. The cooling fan 22 serves to cool the fins 21. An example of the heat transfer member 23 is a heat pipe. The member 23 includes a heat receiving portion thermally connected to the heat receiving plate 24 and a heat radiating portion thermally connected to the radiator fins 21. The heat transfer member 23 receives heat from the heat receiving plate 24 and transfers the received heat to the radiator fins 21.

The following is a detailed description of the semiconductor package 16 and its surroundings.

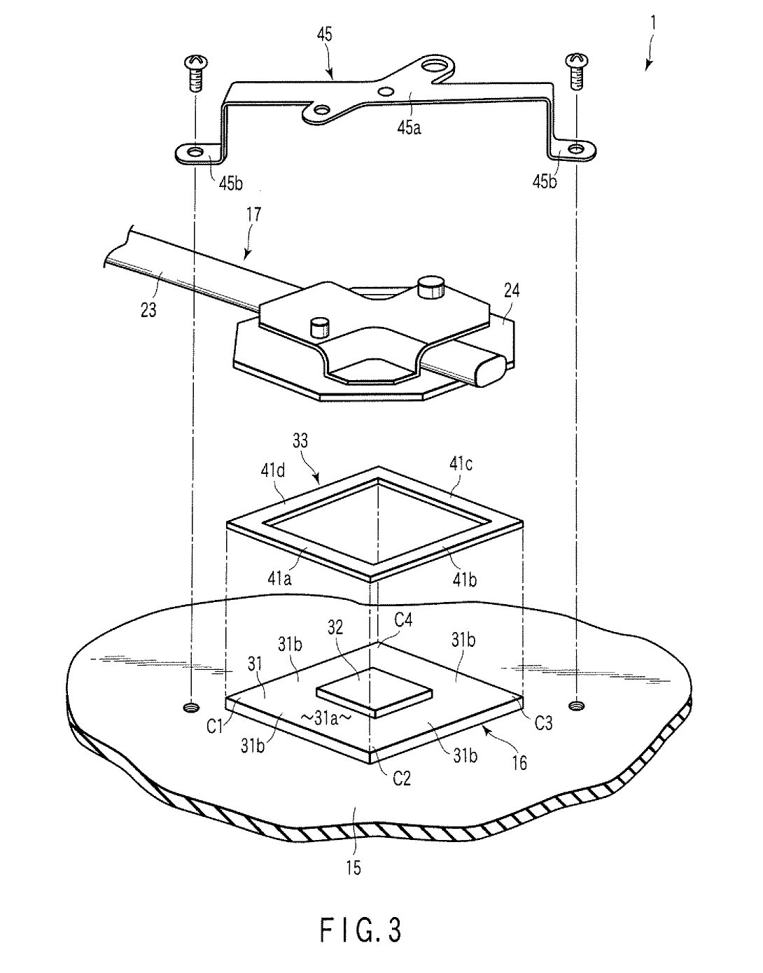

As shown in FIG. 3, the semiconductor package 16 includes a substrate 31 and a silicon die 32. The substrate 31 is square and includes four corner portion C1, C2, C3, and C4. The silicon die 32 is mounted on the central part of the substrate 31. The silicon die 32 is connected electrically and mechanically to the substrate 31. The semiconductor package 16 is connected electrically and mechanically to the printed circuit board 15.

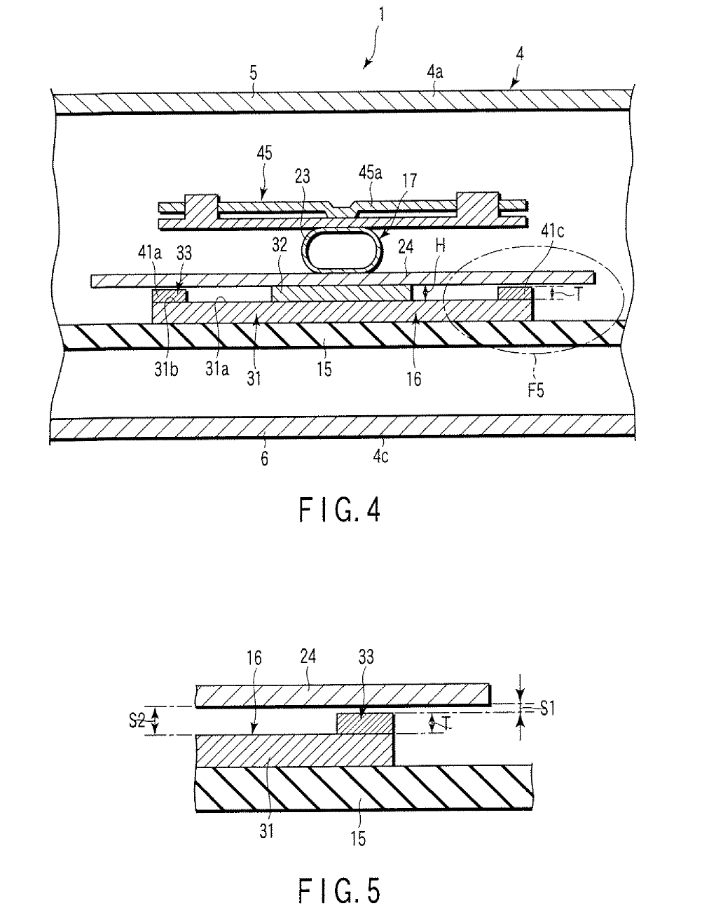

The silicon die 32 is a square piece that is cut out of a silicon base. The silicon die 32 includes four corner portions. As shown in FIG. 4, the die 32 is raised like a step above a surface of the substrate 31. An example of a height H of the die 32 is 0.8 mm.

The heat receiving plate 24 is one size larger than the semiconductor package 16, for example. Examples of the material used for the plate 24 are copper and aluminum. The heat receiving plate 24 is opposed to the silicon die 32. As shown in FIGS. 3 and 4, the heat receiving plate 24 is placed on the silicon die 32 and thermally connected to the silicon die 32. For example, a heat conducting material (not shown) is interposed between the die 32 and the plate 24. An example of the heat conducting material is grease, though a heat conducting sheet may be used instead.

As shown in FIGS. 3 and 4, a gap adjusting member 33 is disposed between the semiconductor package 16 and the heat receiving plate 24. The member 33 is located between the heat receiving plate 24 and a region 31a of the substrate 31 that is apart from the silicon die 32. The gap adjusting member 33 according to the present embodiment is a frame structure that surrounds the silicon die 32. It is formed independently of the semiconductor package 16 and the heat receiving plate 24. An example material for the gap adjusting member 33 is synthetic resin, e.g., rigid plastic. A thickness T of the gap adjusting member 33 is smaller than the height H of the silicon die 32. An example of the thickness T of the member 33 is 0.7 mm.

As shown in FIG. 4, the gap adjusting member 33 is attached to the region 31a of the substrate 31 that is apart from the silicon die 32. As shown in FIG. 5, a gap S1 is secured between the member 33 and the heat receiving plate 24. The gap adjusting member 33 serves to reduce a gap that exists between the substrate 31 and the plate 24. Specifically, a gap S2 of more than about 0.8 mm exists between the substrate 31 and the plate 24 when the member 33 is not mounted. When the member 33 is set in place, on the other hand, the gap S1 of more than about 0.1 mm exists between the substrate 31 and the heat receiving plate 24. Thus, the gap adjusting member 33 fills a part of the gap S2, thereby reducing the gap S2 between the substrate 31 and the heat receiving plate 24.

As shown in FIG. 3, the gap adjusting member 33 according to the present embodiment is a frame that is formed of four sides 41a, 41b, 41c and 41d. The member 33 surrounds the entire periphery of the silicon die 32. The member 33 faces peripheral edge portions 31b and the four corner portions C1, C2, C3 and C4 of the substrate 31 that is square. The four sides 41a, 41b, 41c and 41d of the gap adjusting member 33 may be formed either integrally or separately.

As shown in FIGS. 3 and 4, the computer 1 includes a pressing member 45 which is installed to the heat receiving plate 24. The pressing member includes a body portion 45a and leg portions 45b. The body portion 45a and the leg portions 45b form a plate spring in conjunction with one another. The pressing member 45 presses the heat receiving plate 24 toward the semiconductor package 16. Thus, the heat receiving plate 24 is firmly thermally connected to the silicon die 32.

The following is a description of functions of the portable computer 1.

When the portable computer 1 is being carried about or if it is subjected to any external force, the heat receiving plate 24 is urged to tilt with respect to the semiconductor package 16. According to the portable computer 1 of the present embodiment, however, the heat receiving plate 24 abuts against the gap adjusting member 33 and is restrained from further tilting when it tilts slightly. Thus, the heat receiving plate 24 can never heavily tilt with respect to the semiconductor package 16.

According to the portable computer 1 constructed in this manner, the silicon die 32 can be prevented from being damaged. Specifically, if the gap adjusting member 33 is disposed between the substrate 31 and the heat receiving plate 24, it serves to restrain the heat receiving plate 24 from tilting heavily. If the heat receiving plate 24 is prevented from tilting heavily, that is if the angle of its contact with the die 32 is restricted within a predetermined angle, no great force acts on the die 32 to damage it. Thus, the silicon die 32 can avoid being damaged.

Further, in a mounting process for the heat receiving plate 24 during the manufacture of the portable computer 1, the heat receiving plate 24 may possibly heavily tilt with respect to the semiconductor package 16 and damage the silicon die 32 if the gap adjusting member 33 is not provided. If the adjusting member 33 is set in place, as in the present embodiment, however, the contact angle of the heat receiving plate 24 with respect to the die 32 can be restricted to the predetermined value. Thus, the silicon die 32 can also avoid being damaged in the mounting process for the heat receiving plate 24.

If the thickness T of the gap adjusting member 33 is smaller than the height H of the silicon die 32, the member 33 is not obstructive when the heat receiving plate 24 is thermally connected to the die 32. Despite the presence of the gap adjusting member 33, therefore, the heat receiving plate 24 can be securely thermally connected to the silicon die 32.

If the gap adjusting member 33 surrounds the silicon die 32, the heat receiving plate 24 can be restrained from tilting in any direction. Thus, the silicon die 32 can be prevented more securely from being damaged.

If the gap adjusting member 33 is located opposite the peripheral edge portions 31b of the substrate 31, the heat receiving plate 24 engages the member 33 even when it tilts only slightly. Thus, the tilt of the heat receiving plate 24 can be further reduced.

The four corner portions of the silicon die 32 are the most brittle parts of the silicon die 32. If the gap adjusting member 33 is opposed to the four corner portions C1, C2, C3 and C4 of the substrate 31, the heat receiving plate 24 can be prevented more easily from tilting toward the corner portions of the die 32, so that the die 32 can more securely avoid being damaged.

If the gap adjusting member 33 is formed independently of the semiconductor package 16 and the heat receiving plate 24, the member 33, as well as the package 16 and the plate 24 attached thereto, can enjoy high generality. Thus, the gap adjusting member 33 can be also attached to an existing electronic apparatus, for example.

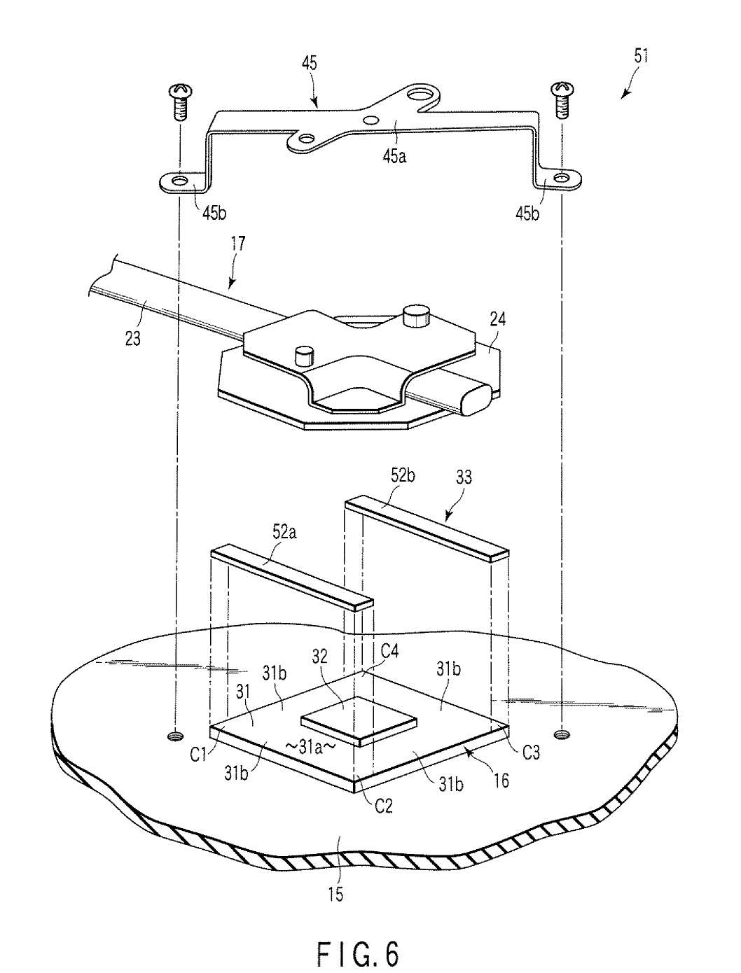

A portable computer 51 as an electronic apparatus according to a second embodiment of the invention will now be described with reference to FIG. 6. Like numerals are used to designate like portions of the portable computers 1 and 51 of the first and second embodiments that have the same functions, and a repeated description of those portions is omitted. The portable computer 51 includes a semiconductor package 16, a heat receiving plate 24, and a gap adjusting member 33.

As shown in FIG. 6, the gap adjusting member 33 includes two oblong pieces 52a and 52b that are formed independently of each other. The oblong pieces 52a and 52b have substantially the same length as their corresponding edges of a substrate 31. The pieces 52a and 52b are attached to peripheral edge portions 31b of the substrate 31 and individually cover two sides of the substrate 31, each extending from one end to the other. The two oblong pieces 52a and 52b cooperate with each other to face four corner portions C1, C2, C3 and C4 of the substrate 31. Further, they cooperate with each other to surround a silicon die 32 from two directions. A thickness T of the oblong pieces 52a and 52b is smaller than a height H of the die 32.

According to the portable computer 51 constructed in this manner, the gap adjusting member 33 restrains the heat receiving plate 24 from tilting heavily, so that the silicon die 32 can be prevented from being damaged.

If the gap adjusting member 33 is opposed to the peripheral edge portions 31b of the substrate 31, the tilt of the heat receiving plate 24 can be further reduced. If the member 33 is opposed to the four corner portions C1, C2, C3 and C4 of the substrate 31, the heat receiving plate 24 can be prevented more easily from tilting toward the corner portions of the die 32. The two oblong pieces 52a and 52b of the gap adjusting member 33 serve for better assemblability and a reduction in cost.

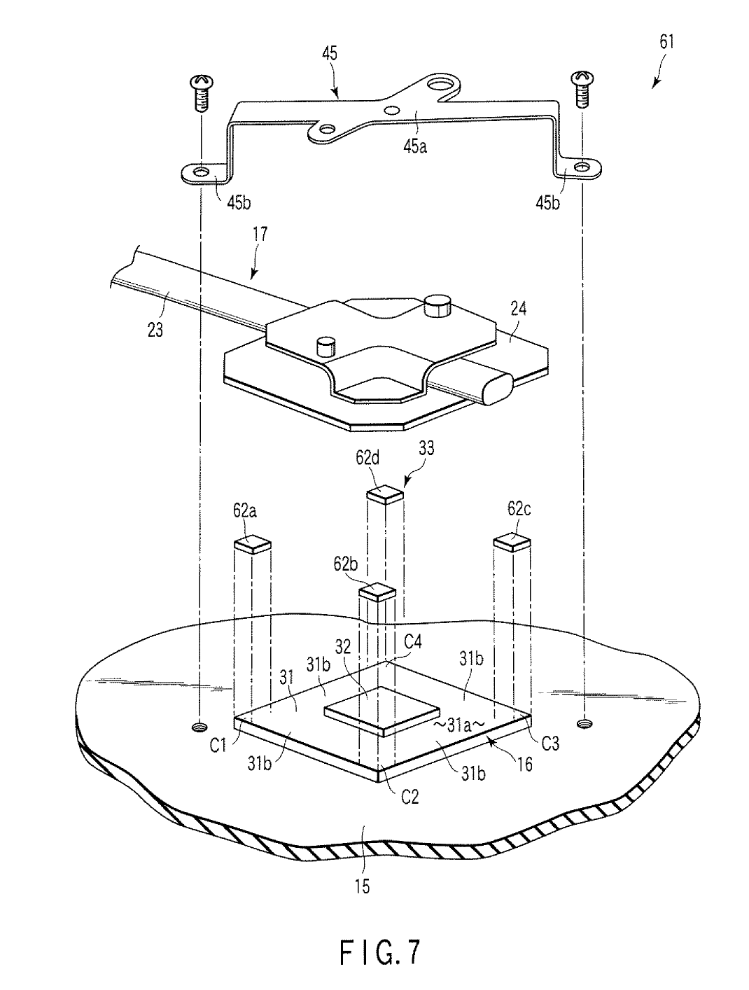

A portable computer 61 as an electronic apparatus according to a third embodiment of the invention will now be described with reference to FIG. 7. Like numerals are used to designate like portions of the portable computers 1, 51 and 61 of the first to third embodiments that have the same functions, and a repeated description of those portions is omitted. The portable computer 61 includes a semiconductor package 16, a heat receiving plate 24, and a gap adjusting member 33.

As shown in FIG. 7, the gap adjusting member 33 includes four square pieces 62a, 62b, 62c and 62d that are formed independently of one another. The square pieces 62a, 62b, 62c and 62d are attached to four corner portions C1, C2, C3 and C4, respectively, of a substrate 31 and cooperate with one another to face the four corner portions C1, C2, C3 and C4. Further, the square pieces 62a, 62b, 62c and 62d cooperate with one another to surround a silicon die 32. A thickness T of the square pieces 62a, 62b, 62c and 62d is smaller than a height H of the die 32.

According to the portable computer 61 constructed in this manner, the gap adjusting member 33 restrains the heat receiving plate 24 from tilting heavily, so that the silicon die 32 can be prevented from being damaged.

If the gap adjusting member 33 is opposed to the four corner portions C1, C2, C3 and C4 of the substrate 31, the heat receiving plate 24 can be prevented more easily from tilting toward the corners of the die 32. If the member 33 surrounds the silicon die 32, the heat receiving plate 24 can be restrained from tilting in any direction.

“Surrounding the silicon die” stated in this invention implies intermittently surrounding the silicon die 32 with the separate pieces 52a, 52b, 62a, 62b, 62c and 62d as in the second and third embodiments, as well as continuously surrounding the entire periphery of the silicon die 32 as in the first embodiment.

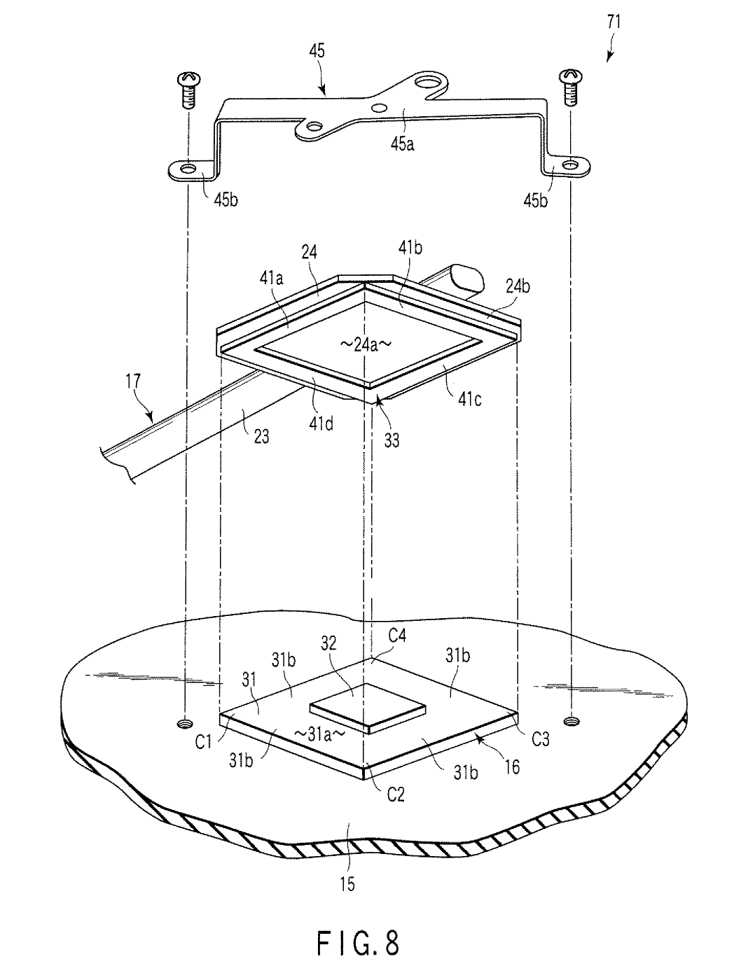

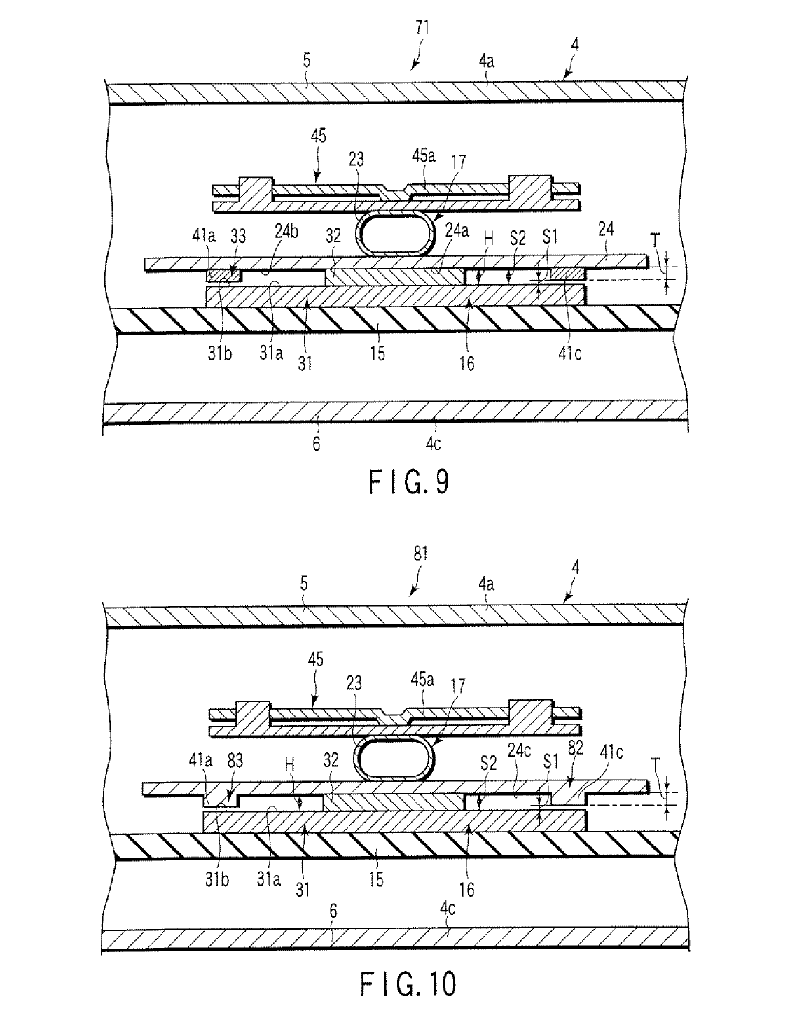

A portable computer 71 as an electronic apparatus according to a fourth embodiment of the invention will now be described with reference to FIGS. 8 and 9. Like numerals are used to designate like portions of the portable computers 1, 51, 61 and 71 of the first to fourth embodiments that have the same functions, and a repeated description of those portions is omitted. The portable computer 71 includes a semiconductor package 16, a heat receiving plate 24, and a gap adjusting member 33. The member 33 is formed independently of the package 16 and the plate 24.

As shown in FIG. 8, the gap adjusting member 33 is attached to a region 24b of the heat receiving plate 24 that is apart from a region 24a opposite a silicon die 32. The member 33 faces peripheral edge portions 31b and four corner portions C1, C2, C3 and C4 of a substrate 31. It surrounds the entire periphery of the silicon die 32. As shown in FIG. 9, a gap S1 is secured between the gap adjusting member 33 and the substrate 31.

According to the portable computer 71 constructed in this manner, the silicon die 32 can be prevented from being damaged. Specifically, if the heat receiving plate 24 is urged to tilt with respect to the semiconductor package 16, the gap adjusting member 33 abuts against the substrate 31 and restrains the heat receiving plate 24 from further tilting when the plate 24 tilts slightly. The silicon die 32 can avoid being damaged unless the heat receiving plate 24 tilts heavily.

The gap adjusting member 33 that is attached to the heat receiving plate 24 is not limited to the form of a frame. Alternatively, it may be formed of two oblong pieces 52a and 52b, such as the ones according to the second embodiment, or four square pieces 62a, 62b, 62c and 62d, such as the ones according to the third embodiment.

A portable computer 81 as an electronic apparatus according to a fifth embodiment of the invention will now be described with reference to FIG. 10. Like numerals are used to designate like portions of the portable computers 1 and 81 of the first and fifth embodiments that have the same functions, and a repeated description of those portions is omitted.

The portable computer 81 includes a semiconductor package 16 and a heat receiving plate 82. The heat receiving plate 82 is opposed to the silicon die 32 and is thermally connected to the die 32. The plate 82 is provided with a raised portion 83. The raised portion 83 protrudes from a surface of the plate 82 toward a region 31a of a substrate 31 that is apart from the silicon die 32. An example raised portion 83 is one that is formed integrally with the heat receiving plate 82. Example materials for forming the plate 82 are copper and aluminum. The raised portion 83 is a metallic structure formed integrally with the heat receiving plate 82, for example.

An example of a projection height T of the raised portion 83 is one that is smaller than a height H of the silicon die 32. An example projection height of the raised portion 83 is 0.7 mm. A gap S1 is secured between the tip end of the raised portion 83 and the substrate 31. The gap S1 between the raised portion 83 and the substrate 31 is smaller than a gap S2 that exists between the substrate 31 and a region 24c of the heat receiving plate 82 that is apart from the raised portion 83.

The raised portion 83 includes four sides 41a, 41b, 41c and 41d, for example, and is in the form of a frame that resembles the gap adjusting member 33 according to the first embodiment. The raised portion 83 faces peripheral edge portions 31b and four corner portions C1, C2, C3 and C4 of the substrate 31. The raised portion 83 surrounds the silicon die 32.

According to the portable computer 81 constructed in this manner, the raised portion 83 fulfills the same function as the gap adjusting member 33. Specifically, the raised portion 83 restrains the heat receiving plate 82 from tilting heavily, so that the silicon die 32 can be prevented from being damaged.

If the raised portion 83 is opposed to the peripheral edge portions 31b of the substrate 31, it can reduce the tilt of the heat receiving plate 82. If the raised portion 83 is opposed to the four corner portions C1, C2, C3 and C4 of the substrate 31, moreover, it can more securely prevent the heat receiving plate 82 from tilting toward the corners of the silicon die 32. If the raised portion 83 surrounds the die 32, the heat receiving plate 82 can be restrained from tilting in any direction.

If the raised portion 83 is formed integrally with the heat receiving plate 82, a process for mounting a gap adjusting member can be omitted. This improves the assemblability of the portable computer 81.

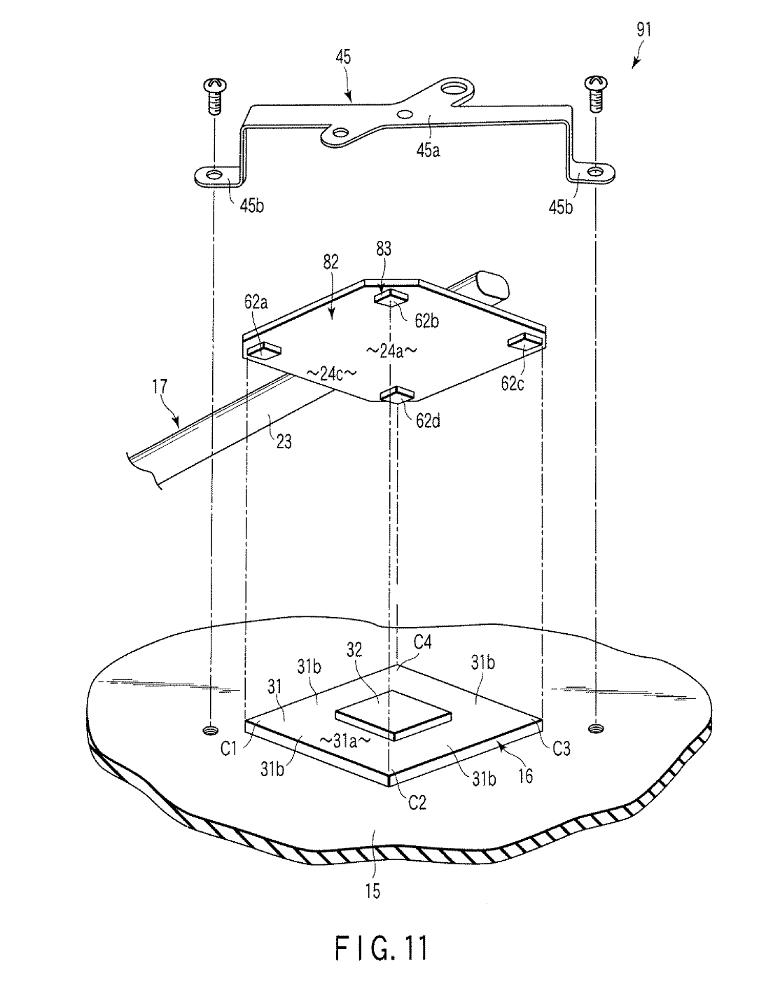

A portable computer 91 as an electronic apparatus according to a sixth embodiment of the invention will now be described with reference to FIG. 11. Like numerals are used to designate like portions of the portable computers 1, 51, 61, 71, 81 and 91 of the first to sixth embodiments that have the same functions, and a repeated description of those portions is omitted.

The portable computer 91 includes a semiconductor package 16 and a heat receiving plate 82. The plate 82 is provided with a raised portion 83. The raised portion 83 protrudes from a surface of the plate 82 toward a region 31a of a substrate 31 that is apart from a silicon die 32.

The raised portion 83 is formed integrally with the heat receiving plate 82. As shown in FIG. 11, the raised portion 83 includes four square pieces 62a, 62b, 62c and 62d that are formed separately from one another. The square pieces 62a, 62b, 62c and 62d cooperate with one another to face four corner portions C1, C2, C3 and C4, respectively, of the substrate 31. An example of a projection height T of the raised portion 83 is one that is smaller than a height H of the silicon die 32. The square pieces 62a, 62b, 62c and 62d cooperate with one another to surround the die 32.

According to the portable computer 91 constructed in this manner, the raised portion 83 restrains the heat receiving plate 82 from tilting heavily, so that the silicon die 32 can be prevented from being damaged. The raised portion 83 may alternatively include two oblong pieces 52a and 52b, such as the ones according to the second embodiment.

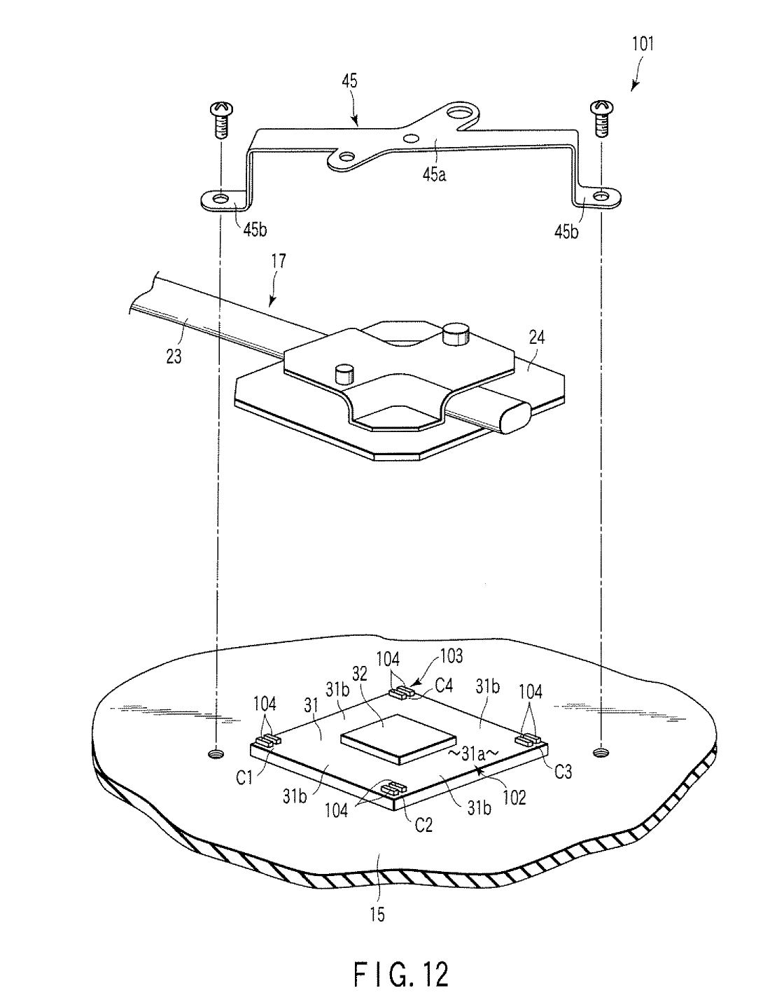

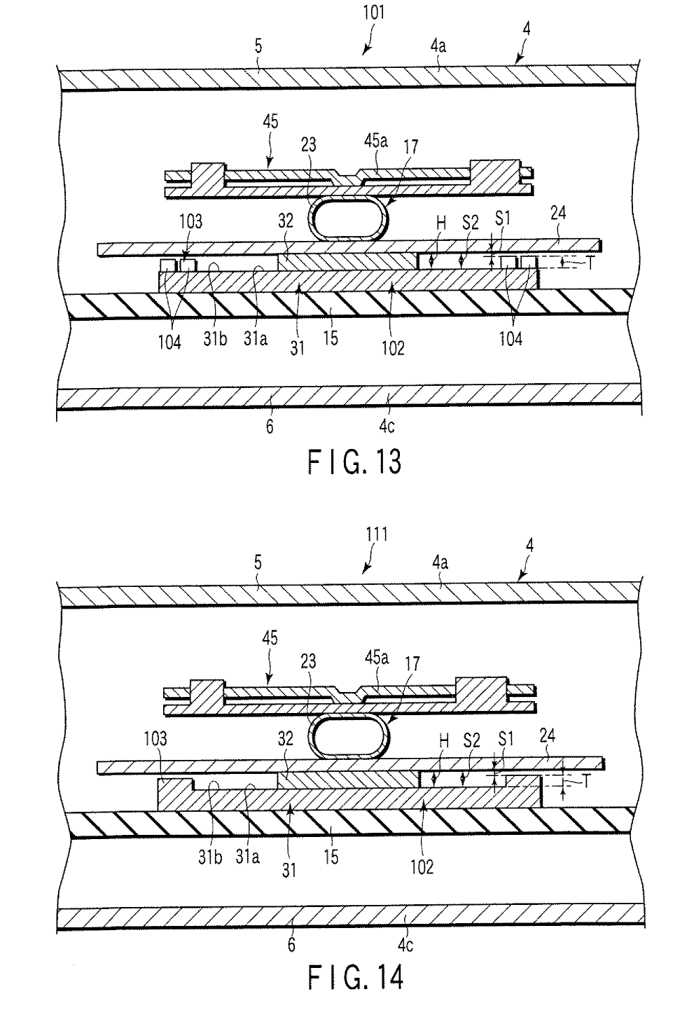

A portable computer 101 as an electronic apparatus according to a seventh embodiment of the invention will now be described with reference to FIGS. 12 and 13. Like numerals are used to designate like portions of the portable computers 1 and 101 of the first and seventh embodiments that have the same functions, and a repeated description of those portions is omitted.

The portable computer 101 includes a semiconductor package 102 and a heat receiving plate 24. The package 102 includes a substrate 31, a silicon die 32, and a raised portion 103. The raised portion 103 is an example of a gap adjusting member according to the present invention. The gap adjusting member according to the present embodiment is formed integrally with the semiconductor package 102.

The raised portion 103 is provided in a region 31a of the substrate 31 that is apart from the silicon die 32 and projects toward the heat receiving plate 24 when the heat receiving plate 24 is attached to the semiconductor package 102. A projection height T of the raised portion 103 is smaller than a height H of the silicon die 32. An example of the projection height T of the raised portion 103 is 0.7 mm. A gap S1 is secured between the raised portion 103 and the heat receiving plate 24. The raised portion 103 serves to reduce a gap which exists between the substrate 31 and the plate 24.

An example of the raised portion 103 is a circuit component 104 which is mounted on the substrate 31. An example of the circuit component 104 is a passive component, such as a capacitor or a resistor. However, the circuit component 104 is not limited to a passive component. An example of the circuit component 104 is a so-called dummy component that is mounted on a surface of the substrate 31 in order to form the raised portion 103. The circuit component 104, a dummy component, is electrically disconnected from the substrate 31.

As shown in FIG. 12, a plurality of circuit components 104 are mounted individually on four corner portions C1, C2, C3 and C4 of the substrate 31. The circuit components 104 cooperate with one another to surround the silicon die 32. A mounting height T of the circuit component 104 is smaller than the height H of the silicon die 32.

According to the portable computer 101 constructed in this manner, the raised portion 103 of the semiconductor package 102 fulfills the same function as the gap adjusting member 33. Specifically, the raised portion 103 restrains the heat receiving plate 24 from tilting heavily, so that the silicon die 32 can be prevented from being damaged.

If the raised portion 103 as the gap adjusting member is formed integrally with the semiconductor package 102, a process for mounting a gap adjusting member can be omitted. This improves the assemblability of the portable computer 101. If the circuit component 104 is used to form the raised portion 103, the raised portion 103 can be provided more easily on the surface of the substrate 31 than by any other method.

If the raised portion 103 is disposed on the four corner portions C1, C2, C3 and C4 of the substrate 31, it can prevent the heat receiving plate 24 from tilting toward the corners of the silicon die 32.

A portable computer 111 as an electronic apparatus according to an eighth embodiment of the invention will now be described with reference to FIG. 14. Like numerals are used to designate like portions of the portable computers 1, 51, 61, 71, 81, 91, 101 and 111 of the first to eighth embodiments that have the same functions, and a repeated description of those portions is omitted.

The portable computer 111 includes a semiconductor package 102 and a heat receiving plate 24. The package 102 includes a substrate 31, a silicon die 32, and a raised portion 103. The raised portion 103 according to the present embodiment is formed by raising a part of the substrate 31 like a step.

The raised portion 103 may be in the form of a frame that resembles the gap adjusting member 33 according to the first embodiment. Alternatively, it may be formed including two oblong pieces 52a and 52b, such as the ones according to the second embodiment, or square pieces 62a, 62b, 62c and 62d, such as the ones according to the third embodiment.

According to the portable computer 111 constructed in this manner, the raised portion 103 of the semiconductor package 102 restrains the heat receiving plate 24 from tilting heavily, so that the silicon die 32 can be prevented from being damaged.

Although the portable computers 1, 51, 61, 71, 81, 91, 101 and 111 of the first to eighth embodiments and the semiconductor package 102 have been described herein, the present invention is not limited to these embodiments. The components of the first to eighth embodiments may be suitably used in combination with one another.

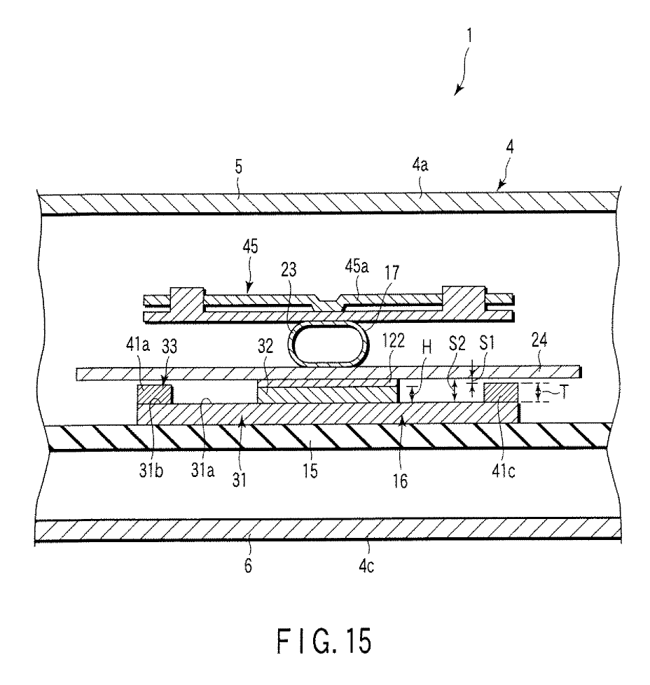

A modification of the portable computer 1 will now be described with reference to FIG. 15. In this portable computer 1, a thick heat transfer material 122 is interposed between a heat receiving plate 24 and a silicon die 32. An example of the heat transfer material 122 is a heat transfer sheet. A gap adjusting member 33 has a thickness T larger than a height H of the die 32.

More specifically, the thickness T of the gap adjusting member 33 or the projection height T of the raised portion 83 or 103 according to each of the embodiments are not limited to the size smaller than the height H of the silicon die 32. For example, it may be about 0.1 mm, for example, smaller than the gap S2 between the substrate 31 and the heat receiving plate 24 or 82.

The heat receiving plate according to the present invention is not limited to the one to which the heat transfer member is attached, but may be one that is used singly as a heat sink.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a semiconductor package including a substrate and a silicon die mounted on the substrate;
a heat receiving plate opposed to the silicon die and thermally connected to the silicon die; and
a gap adjusting member which is disposed between the heat receiving plate and a region of the substrate apart from the silicon die and serves to reduce a gap which exists between the substrate and the heat receiving plate.

2. An electronic apparatus according to claim 1, wherein the gap adjusting member surrounds the silicon die.

3. An electronic apparatus according to claim 1, wherein the gap adjusting member faces a peripheral edge portion of the substrate.

4. An electronic apparatus according to claim 1, wherein the substrate is square and includes four corner portions, and the gap adjusting member faces the four corner portions of the substrate.

5. An electronic apparatus according to claim 1, wherein the gap adjusting member is formed independently of the semiconductor package and the heat receiving plate and attached to the substrate so that a gap is secured between the gap adjusting member and the heat receiving plate.

6. An electronic apparatus according to claim 1, wherein the gap adjusting member is formed independently of the semiconductor package and the heat receiving plate and attached to the heat receiving plate so that a gap is secured between the gap adjusting member and the substrate.

7. An electronic apparatus according to claim 1, wherein the gap adjusting member is a circuit component which is mounted on the substrate and electrically disconnected from the substrate.

8. An electronic apparatus comprising:
a semiconductor package including a substrate and a silicon die mounted on the substrate; and
a heat receiving plate opposed to the silicon die and thermally connected to the silicon die,
the heat receiving plate being provided with a raised portion which projects toward a region of the substrate apart from the silicon die.

9. A semiconductor package to which a heat receiving plate is to be thermally connected, comprising:
a substrate;
a silicon die mounted on the substrate; and
a raised portion provided in a region of the substrate apart from the silicon die and projecting toward the heat receiving plate when the heat receiving plate is attached to the semiconductor package.

10. A semiconductor package according to claim 9, wherein the raised portion is a circuit component which is mounted on the substrate and electrically disconnected from the substrate.
